(19) United States
(12) Patent Application Publication
(10) Pub. No.: US 2007/0241384 A1
(43) Pub. Date: Oct. 18, 2007

(54) Methods and apparatus for non-volatile semiconductor memory devices

(75) Inventor: Yiming Zhu, Belmont, CA (US)

Correspondence Address: EMIL CHANG;LAW OFFICES OF EMIL CHANG, 874 JASMINE DRIVE, SUNNYDALE, CA, 94086, US

(73) Assignee: GigaDevice Semiconductor Inc.

(21) Appl. No.: 11/404,194

(22) Filed: Apr. 14, 2006

(51) Int. Cl. H01L 29/76

(52) U.S. Cl. 257/314

(57) ABSTRACT

The present invention provides methods and apparatuses for a non-volatile semiconductor memory device. A non-volatile semiconductor memory device having multiple layers to provide a source, a drain, and a floating gate, comprising a plurality of metal layers to provide interconnects to the non-volatile memory wherein at least two of the plurality of metal areas on one or more layers are configured to provide a capacitor having a capacitance that is capacitively coupled to the floating gate.

### FIELD OF INVENTION

The present invention relates to memory devices, in particular to non-volatile memory devices.

### BACKGROUND

A floating gate non-volatile memory cell store information by storing an electrical charge on the floating gate. The floating gate is capacitively coupled to a control gate. In order to write to a cell, a potential difference is created between the control gate and some other region such as a source, drain, or channel region of the cell. The voltage on the control gate is capacitively coupled to the floating gate so as to cause a potential difference between the floating and the source, drain or channel region. As in the case of a write, the potential difference is used to place a charge on the floating gate.

As integrated devices become smaller and smaller, SoC (System on Chip) is becoming more and more common. An essential building block is the non-volatile memory. In order to provide the many functions of a SoC, many different function blocks must be integrated into one chip. However, today's SoC is primarily based on logic process, and the non-volatile memory is generally handled using a specialty process other than the logic process. The logic process is the dominant process and is popular with IC designers. Since the specialty processes are less common, it is often much more expensive and adds substantial costs to the development of the SoC device.

One solution is to fabricate entire SoC using the specialty process for the non-volatile memory devices. However, using this approach, the performance of the other logic devices is sacrificed for the benefit of ease in fabricating the non-volatile memory devices. Since many IC designers are not as familiar with the specialty processes as the traditional logic process approach, designs becomes more risky and complicated. A further disadvantage is the high cost and lagged support. Since the specialty processes are not widely used within the semiconductor fabrication community, lagged technical support is often associated with the specialty processes which can cause delays in developing the SoC.

Many approaches have been introduced to solve the issue of conformity with non-volatile memory devices and the traditional logic process. Designers have adopted to using a pair of pmos (positive channel metal oxide silicon) and nmos (negative channel metal oxide silicon) devices that are coupled with both of their gates connected and floated. The floated poly gate is used to store charge. Program and erase functions are enabled thru mosfet tunneling and other physical effects. However, in order to avoid a latch-up during high-voltage operation between pmos and nmos devices, this memory cell has to be made large. In addition, capacitance ratio is determined by the nmos and pmos capacitances. Since nmos and pmos work in different modes, that is, one is in accumulation mode, and the other is in inversion mode, they produce non-linear capacitance. The non-linear capacitance effects of the nmos and pmos devices require additional circuitry and special attention to achieve desired linear behavior in the memory devices.

Others have used soft and hard breakdown effects to generate a series of different resistance so that stored value can be differentiated and recognized. However, due to difficulty in controlling the breakdown and unknown effects in the breakdown process, those devices have very limited times of programmability.

Accordingly, there is a need for a non-volatile memory cell design that is compatible with well-known proven logic process which overcomes the disadvantages of earlier attempts while maintaining compactness and reliability in the memory cell.

### SUMMARY OF INVENTION

The present invention discloses methods and apparatuses for a non-volatile semiconductor memory device. In accordance with an embodiment, the non-volatile memory structure takes advantage of capacitance between metal areas on one or more metal layers that may be used for interconnects. The capacitance formed from the one or more metal areas on one or more metal layers has advantages of being more linear and can be formed using well-known proven process techniques of fabrication. Accordingly, embodiments of the present invention disclose a non-volatile semiconductor memory device having multiple layers to provide a source, a drain, and a floating gate, comprising a plurality of metal areas on one or more metal layers to provide interconnects to the non-volatile memory wherein at least two of the plurality of metal areas on one or more metal layers are configured to provide a capacitor having a capacitance that is capacitively coupled to the floating gate.

In accordance with another aspect of the present invention, the non-volatile semiconductor comprise a via coupling the at least two of the plurality of metal areas on one or more metal layers to form the capacitor.

In accordance to yet another aspect of the present invention, at least two of the plurality of metal areas that provide the interconnects to the non-volatile memory are electrically isolated from the at least two of the plurality of metals areas that form the capacitor.

Other aspects and advantages of the present invention will become apparent to those skilled in the art from reading the following detailed description when taken in conjunction with the accompanying drawings.

### BRIEF DESCRIPTION OF DRAWINGS

FIG. 1 illustrates a cross-sectional view of a pmos type non-volatile programmable memory cell in accordance with an embodiment of the present invention;

FIG. 2 illustrates a cross-sectional view of a nmos type non-volatile programmable memory cell in accordance with an embodiment of the present invention.

FIG. 3 illustrates a top view of a non-volatile programmable memory cells in accordance with an embodiment of the present invention;

FIG. 4 illustrates a cross-sectional view of a pmos type non-volatile programmable memory cell in accordance with another embodiment of the present invention; and

FIG. 5 illustrates a cross-sectional view of a nmos type non-volatile programmable memory cell in accordance with another embodiment of the present invention.

### DETAILED DESCRIPTION

The present invention will now be described in detail with reference to preferred embodiments as illustrated in the accompanying figures. During the description, specific details are set forth in order to provide a thorough understanding of the present invention. However, it will be apparent to one skilled in the art that the present invention may be practiced without some or all of the specific details. In order to not unnecessarily obscure the present invention, some well know process steps or structures may not have been described in detail.

In one embodiment, the present invention relates to semiconductor memories, and more particularly to non-volatile memories and structures of such which provide efficient fabrication and functionality of the memories using preferred logic process of manufacturing. The present invention takes geometric advantage of inherent layering of materials at reduced ratios in sub-micron process.

In modern device and advanced process technology, coupling capacitance between metals is becoming a majority part of the overall capacitance, while the weight of plate capacitance becomes less. For example, minimal metal separation is 0.3 um on a typical 0.25 um technology, and this is 0.23 um on a typical 0.18 um. It makes coupling capacitance between the same layer metals with minimal separation increase 30%, while gate capacitance (the same area) over the generation is kept the same, that is, gate capacitance for minimal geometry becomes smaller. Overall, it makes coupling capacitance between the same layer metals overtake values from gate capacitor and a flash cell with such a structure has the correct capacitance ratio for proper memory operation, such as, program, erase, and read.

Accordingly, in accordance to an embodiment of the present invention, a pmos device works as programmable cell, and a metal-insulator-metal works as coupling capacitor. In practice, the coupling capacitor is typically set to be 5-10 times of the capacitance of the programmable cell. In a present embodiment, the programmable cell is a PMOS device based on standard logic process. In general, standard logic process offers at least two types of devices: core devices and I/O devices. I/O devices have thicker oxides and operate at higher voltages. To use the I/O device for programmable cells, oxide thickness of programmable cells is typically more than 70 Angstroms. Operating the programmable cells at 3.3V for I/O device logic process meets the standard logic requirement. However, in order to keep devices small, for sub-micron device, for example, 0.18 um and 0.13 um, line width of a thin device could be used for such purpose with a process step to increase oxide thickness of such device to that of I/O device cell. Accordingly, the coupling capacitor or control gate for the programmable memory cell can be fabricated using the standard logic process.

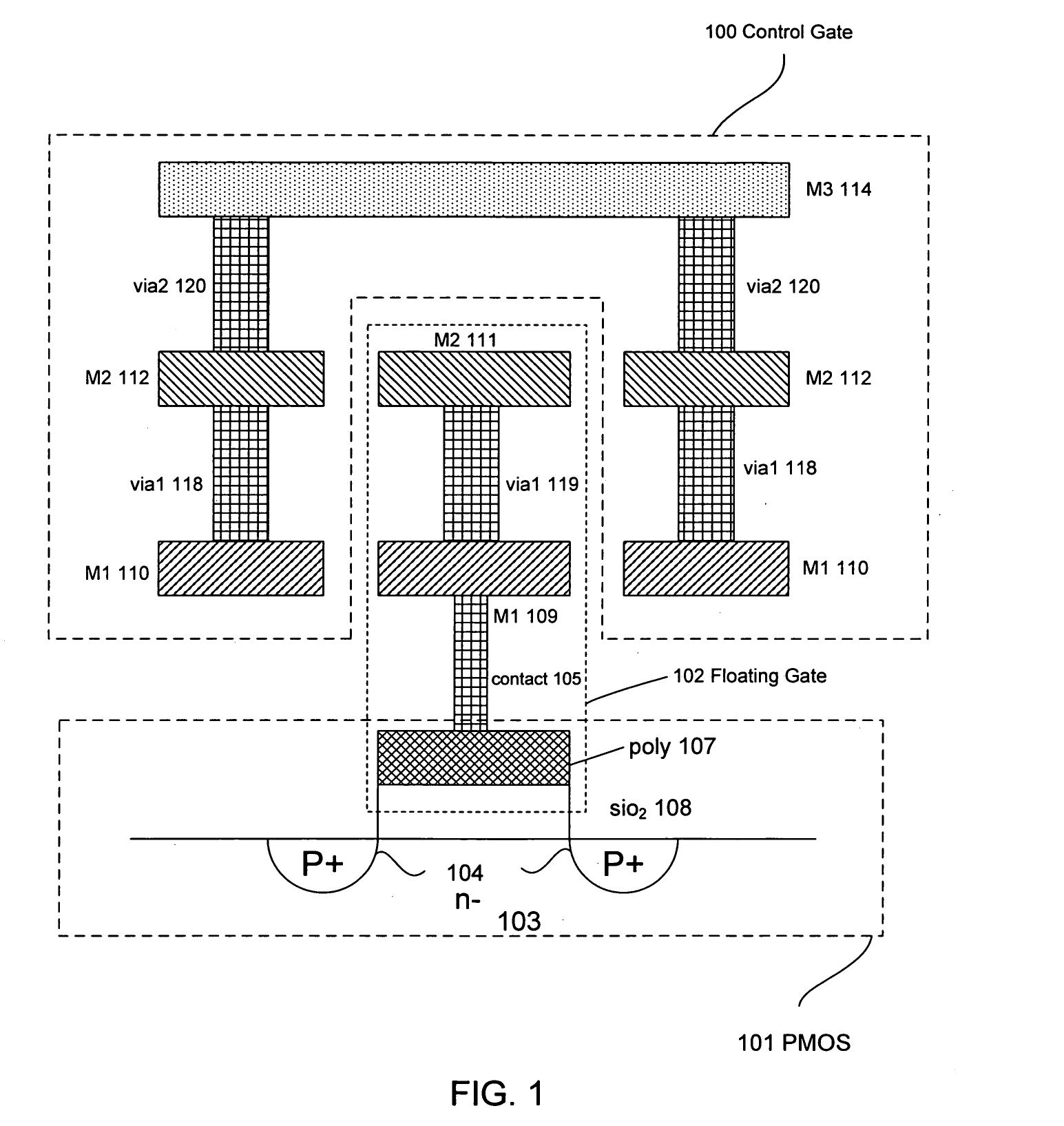

The features and advantages of the present invention can be better understood with reference to the figures and the description which follow. In accordance to a present embodiment, FIG. 1 is a cross-sectional view of a pmos type non-volatile memory cell on wafer which includes a control gate 100 configured to have a capacitance and a pmos type floating gate memory cell 101 having a floating gate 102. The floating gate memory cell 101 consists of a pmos device formed in a n-substrate 103 with p⁺ diffusion 104 for a source and drain. A floating gate 102 includes a SiO₂ layer 108, a polysilicon layer 107 coupled to a metal 1 109 using a contact 105, and the metal 1 109 coupled to metal 2 111 thru vial 119. The floating gate is surrounded by insulators. The control gate 100 includes a metal 1 layer 110, a metal 2 layer 112, and a metal 3 layer 114. Via 1 118 electrically couples metal 1 layer 110 with metal 2 layer 112. Via 2 120 electrically couples metal 2 layer 112 with metal 3 layer 114. Metal 1 layer 110 and metal 2 layer 112 enclose the floating gate 102, and the metal 3 layer 114 covers the entire memory cell. Metal 1 layer 110 and metal 2 layer 112 as illustrated each shows two metal areas but it shall be understood that each metal layer may have one or more metal areas.

Since the capacitance is formed by the coupling of two or more metal areas on one or more metal layers, it is scalable with technology shrinkage. In addition, the metal layer to metal layer capacitor has better linearity and stability than mos capacitances.

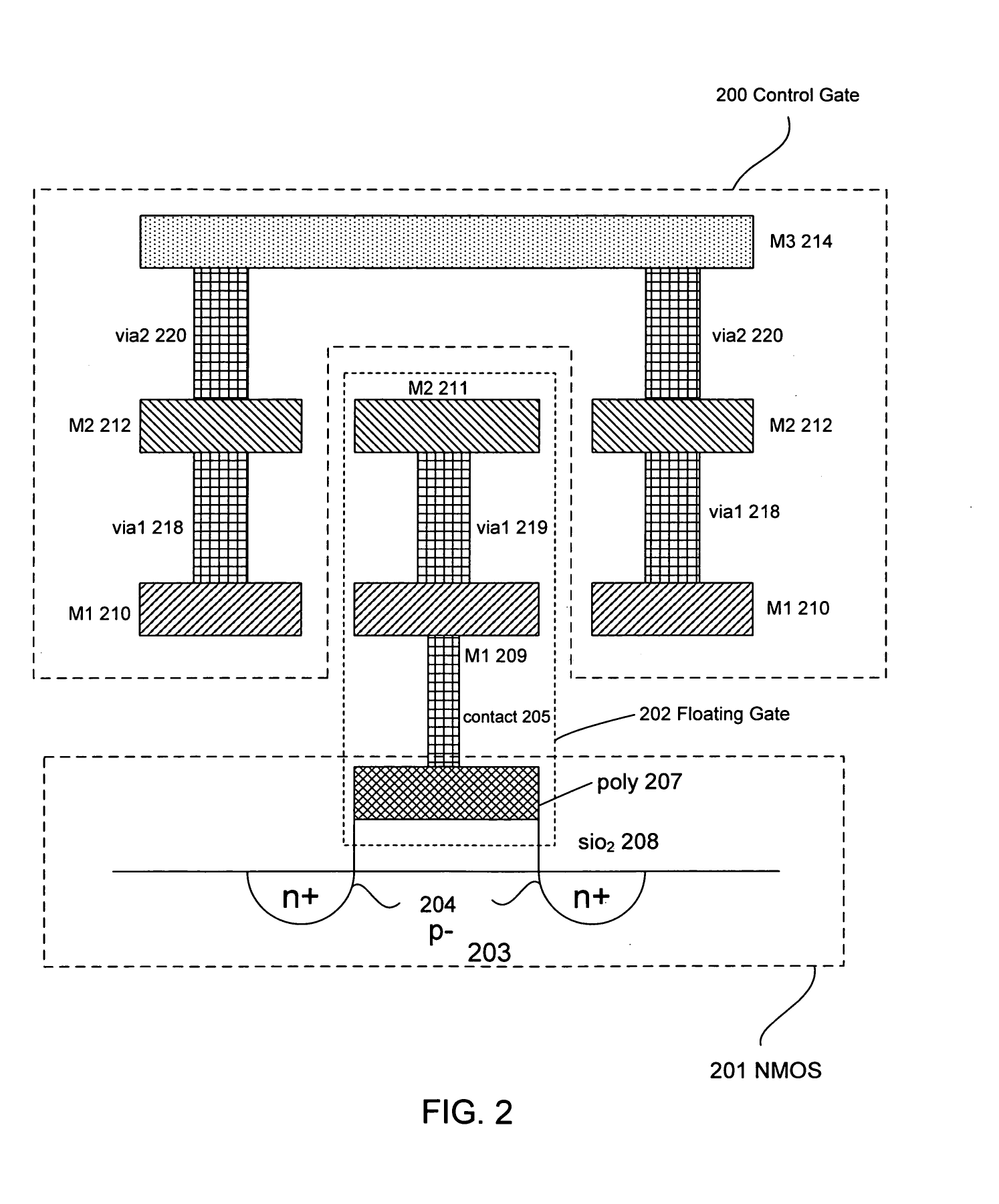

FIG. 2 shows a cross section view of an embodiment of a nmos type non-volatile memory cell in accordance with the present invention. The nmos type non-volatile memory which includes a control gate 200 configured to have a capacitance and a nmos type floating gate memory cell 201 having a floating body 202. The floating gate memory cell 201 consists of a nmos device formed in a p⁻ substrate 203 with n⁺ diffusion 204 for a source and drain. A floating gate 202 includes a SiO₂ layer 208, a polysilicon layer 207 coupled to a metal 1 209 using a contact 205, and the metal 1 209 coupled to metal 2 211 thru vial 219. The floating gate 202 is surrounded by insulators. The control gate 200 includes a metal 1 layer 210, a metal 2 layer 212, and a metal 3 layer 14. Via 1 218 electrically couples metal 1 layer 210 with metal 2 layer 212. Via 2 220 electrically couples metal 2 layer 212 with metal 3 layer 114. Metal 1 layer 210 and metal 2 layer 212 enclose the floating gate 202, and the metal 3 layer 214 covers the entire memory cell. Metal 1 layer 210 and metal 2 layer 212 as illustrated each shows two metal areas but it shall be understood that each metal layer may have one or more metal areas.

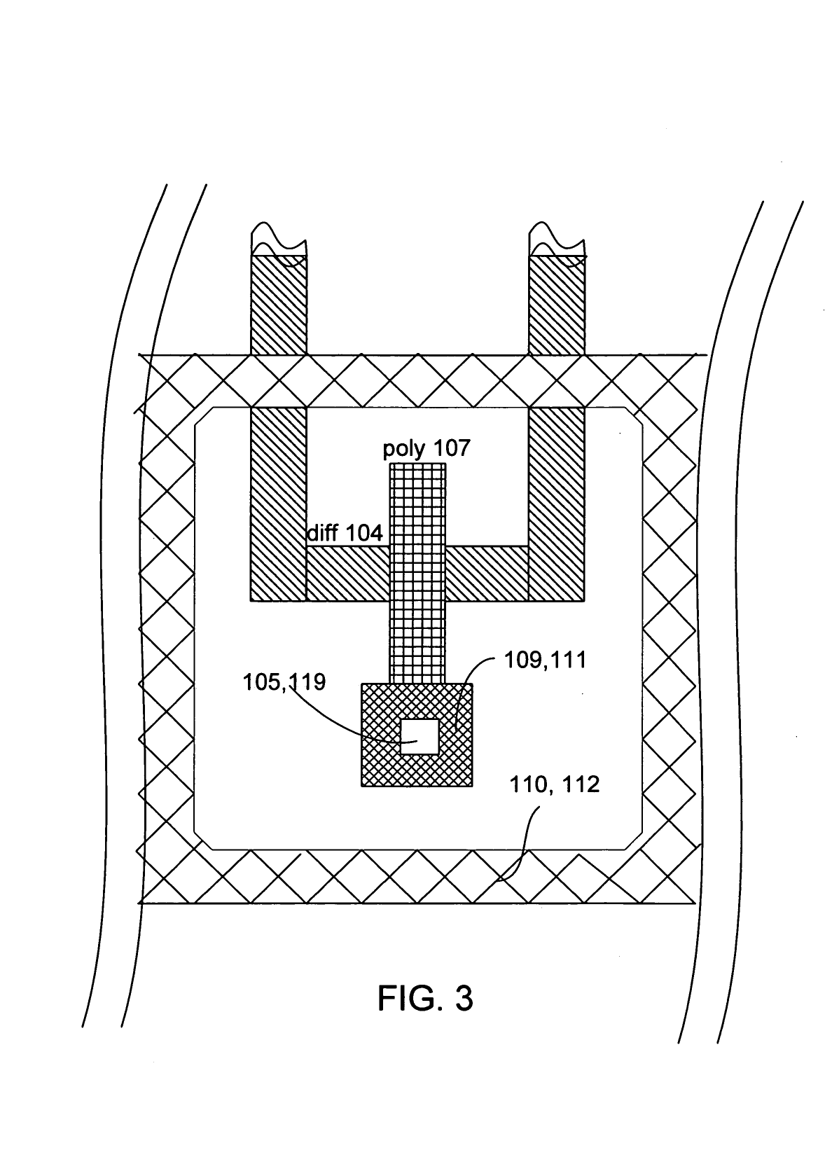

FIG. 3 shows a top view of the non-volatile memory cell of FIG. 1. The metal layers 110, 112 and contact 105, and vial 119 are shown. The polysilicon layer 107 and p⁺ diffusion 104 are also shown. Accordingly, from the top view, the metal 1 layer 109 and metal 2 layer 111 enclose the floating gate, and the metal 3 layer covers the entire cell. For clarity, metal layer 114 is not shown in the top view.

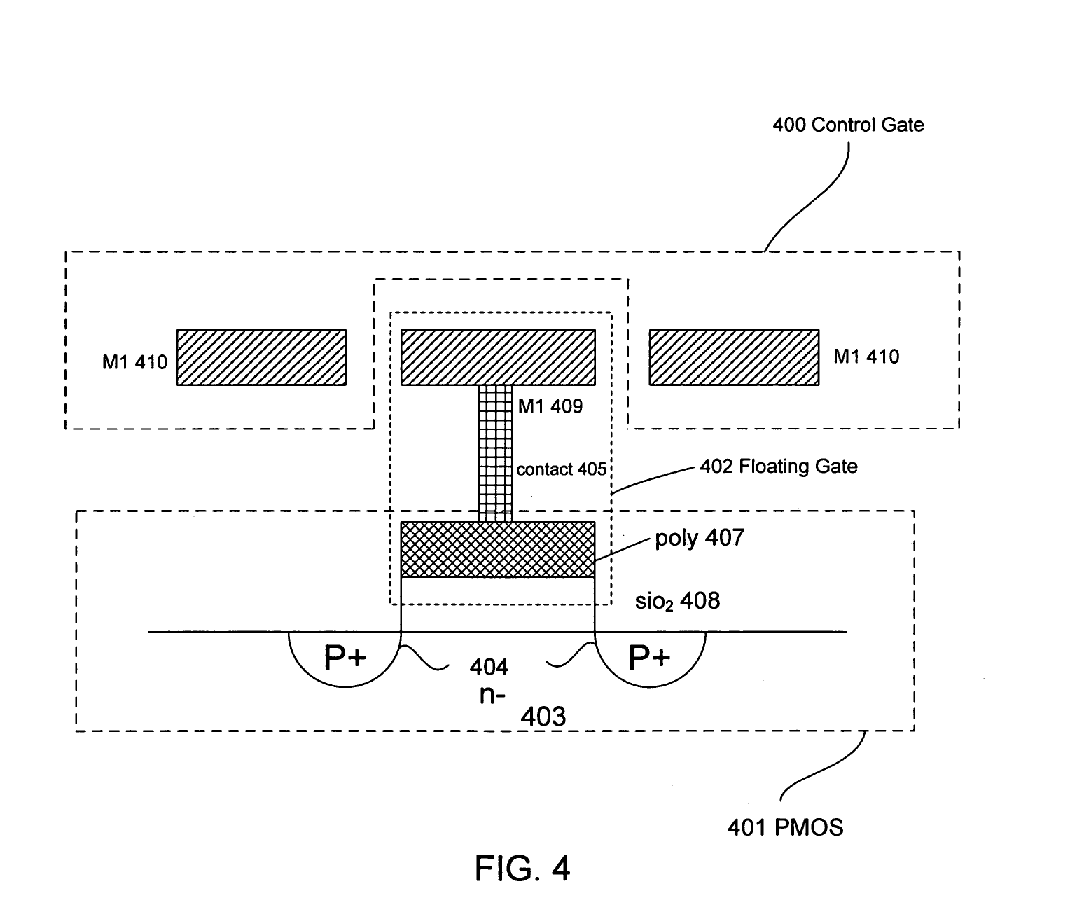

In accordance to another embodiment of the invention, FIG. 4 show a cross-sectional view of a pmos type non-volatile memory cell on wafer which includes a control gate 400 configured to have a capacitance and a pmos type floating gate memory cell 401 having a floating gate 402. The floating gate memory cell 401 consists of a pmos device formed in a n⁻ substrate 403 with p⁺ diffusion 404 for a source and drain. A floating gate 402 includes a SiO₂ layer 408, a polysilicon layer 407 coupled to a metal 1 409 using a contact 405. The floating gate is surrounded by insulators. The control gate 400 includes metal 1 layers 410 which capacitively couples to the floating gate 402. It is appreciated that the floating gate 402 can be capacitively coupled to either one or both of the metal areas on metal layer 410 as shown in FIG. 4. As line widths continue to become smaller, the capacitance between the metals is scaled to form the control gate 400. Furthermore, as a feature of the present invention, it should be noted that the metal areas on one or more metal layers (either on the same layer or different layers where the layers may be any type of layers) can be designed and utilized in providing the necessary capacitance for any of the embodiments.

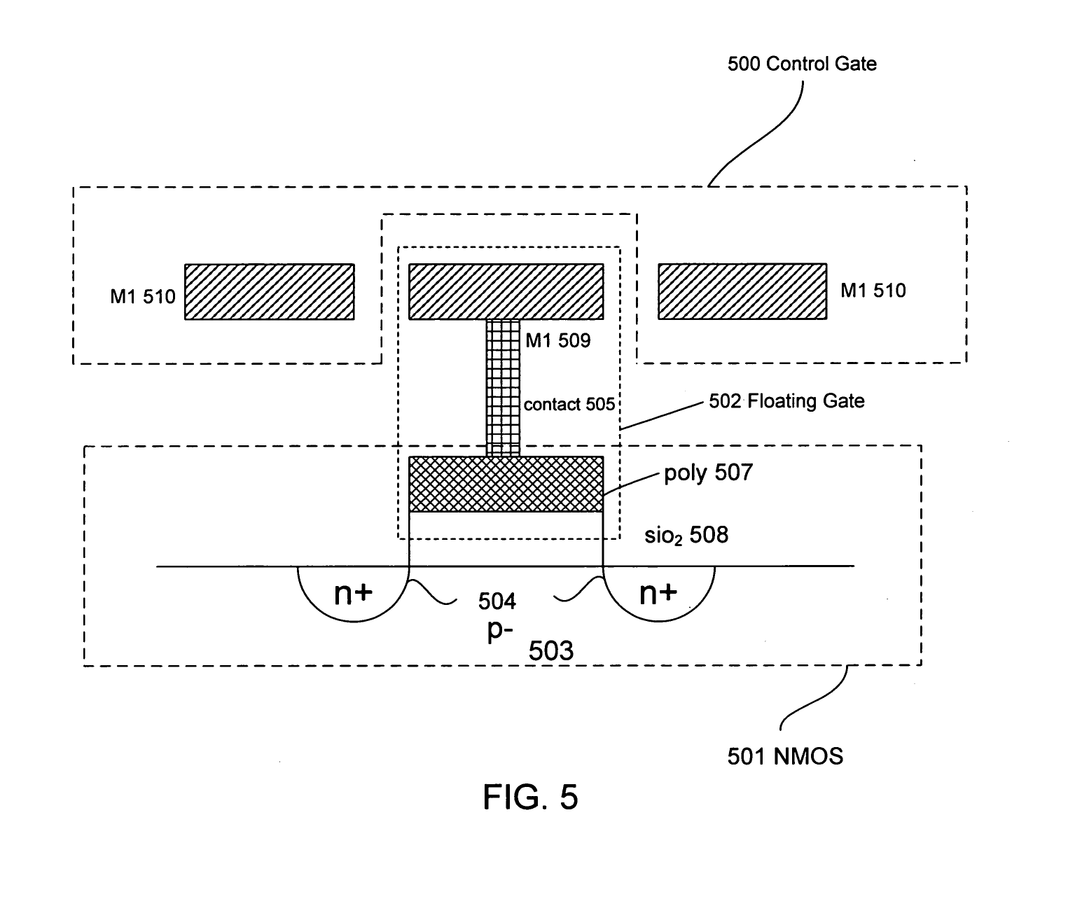

FIG. 5 shows a cross section view of another embodiment of a nmos type non-volatile memory cell in accordance with the present invention. The nmos type non-volatile memory which includes a control gate 500 configured to have a capacitance and a nmos type floating gate memory cell 501 having a floating gate 502. The floating gate memory cell 501 consists of a nmos device formed in a p⁻ substrate 503 with n⁺ diffusion 504 for a source and drain. A floating gate 502 includes a SiO₂ layer 508, a polysilicon layer 507 coupled to a metal 1 509 using a contact 505. The floating gate 502 is surrounded by insulators. The control gate 500 includes a metal 1 layer 510 which capacitively couples to the floating gate 502. It is appreciated that the floating gate 502 can be capacitively coupled to either one or both a left metal layer 510 and a right metal layer 510 as shown in FIG. 5. As line widths continue to become smaller, the capacitance between the metals is scaled to form the control gate 500. Furthermore, as a feature of the present invention, it should be noted that the metal areas on one or more layers (either on the same layer or different layers where the layers may be any type of layers) can be designed and utilized in providing the necessary capacitance for any of the embodiments.

In accordance to another embodiment of the present invention, the diffusion layer 104, 204, 404, or 504 is used to provide the interconnects to the memory cells including the bit lines. In this case, the metal layers can be better isolated from the interconnects and the metal layers can be more fully used to provide capacitance.

As can be appreciated from the foregoing, the disclosed non-volatile memory cell takes advantage of shrinking geometries and the inherent capacitance associated with close proximity of the metal layer to provide control gate capacitance for controlling the charge on the floating gate. Although the present invention has been described using pmos and nmos transistors, other transistors technologies are equally applicable.

While the invention has been described in details with reference to the present embodiment, it shall be appreciated that various changes and modifications are possible to those skilled in the art without departing the spirit of the invention. Thus, the scope of the invention is intent to be solely defined in the accompanying claims.

What is claimed is:

1. A non-volatile semiconductor memory device having multiple layers to provide a source, a drain, and a floating gate, comprising a plurality of metal areas on one more more layers to provide interconnects to the non-volatile memory wherein at least two of the plurality of metal areas are configured to provide a capacitor having a capacitance that is capacitively coupled to the floating gate.

2. The non-volatile semiconductor memory device of claim 1, wherein the capacitor is a control gate.

3. The non-volatile semiconductor memory device of claim 1 further comprising a via coupling the at least two of the plurality of metal areas to form the capacitor.

4. The non-volatile semiconductor memory device of claim 1, wherein the at least two of the plurality of metal areas providing the interconnects to the non-volatile memory are electrically isolated from the at least two of the plurality of metals areas that form the capacitor.

5. The non-volatile semiconductor memory device of claim 2, wherein the control gate includes a plurality of capacitors.

6. The non-volatile semiconductor memory device of claim 5, wherein the plurality of capacitors are formed using the at least two of the plurality of metal areas on one or more layers.

7. The non-volatile semiconductor memory device of claim 6 further comprising another capacitor formed using another metal area and one of the at least two of the plurality of metal areas wherein the another capacitor is capacitively coupled to the plurality of capacitors.

8. The non-volatile semiconductor memory device of claim 6, wherein the floating gate is configured to electrically couple to the plurality of capacitors.

9. The non-volatile semiconductor memory device of claim 1, wherein the memory device is formed using pmos.

10. The non-volatile semiconductor memory device of claim 1, wherein the memory device is formed using nmos.

11. A non-volatile semiconductor memory system having multiple layers to form a plurality of non-volatile memory devices, each memory device having a source, a drain, a floating gate, a control gate coupled to the floating gate, and interconnects to a plurality of other non-volatile memory devices, comprising:
at least one metal layer wherein the control gate includes a capacitance formed using the at least one metal layer.

12. The non-volatile semiconductor memory system of claim 11, wherein the at least one metal layer includes two metal areas.

13. The non-volatile semiconductor memory system of claim 12, wherein the control gate includes a via to couple the two metal areas.

14. The non-volatile semiconductor memory system of claim 12, wherein the plurality of metal areas form interconnects to the non-volatile memory and is electrically isolated from the plurality of metals areas that form the capacitance.

15. The non-volatile semiconductor memory system of claim 12 further comprising a plurality of capacitors to form the capacitance.

16. The non-volatile semiconductor memory system of claim 15 further comprising another capacitor formed using another metal layer and one of the two metal areas wherein the another capacitor is capacitively coupled to the plurality of capacitors.

17. The non-volatile semiconductor memory system of claim 11 further comprising a diffusion layer configured to interconnect the plurality of non-volatile memory devices.

18. A method of forming a plurality of non-volatile memory semiconductor devices wherein each device includes multiple layers to provide a source, a drain, a floating gate, and a control gate coupled to the floating gate, comprising the steps: interconnecting a plurality the devices using a plurality of metal areas; and forming the control gate using the plurality of metal areas to provide a capacitance.

19. The method of claim 18, wherein the plurality of metal areas includes one or more metal layers.

20. The method of claim 18 further comprising the step of forming a via to couple the one or more metal areas.
